(19) United States
(12) Patent Application Publication
(10) Pub. No.: US 2020/0083606 A1
(43) Pub. Date: Mar. 12, 2020

(54) ANTENNA DEVICE AND PRINTED CIRCUIT BOARD

(71) Applicants: LITE-ON ELECTRONICS (GUANGZHOU) LIMITED, Guangzhou (CN); Lite-On Technology Corporation, Taipei (TW)

(72) Inventor: Tzung-Fang Huang, Taipei (TW)

(73) Assignees: LITE-ON ELECTRONICS (GUANGZHOU) LIMITED, Guangzhou (CN); Lite-On Technology Corporation, Taipei (TW)

(21) Appl. No.: 16/243,092

(22) Filed: Jan. 9, 2019

(30) Foreign Application Priority Data
Sep. 7, 2018 (CN) 201811041315.5

(51) Int. Cl. H01Q 9/04; H01Q 1/48; H05K 1/02

(52) U.S. Cl. CPC H01Q 9/0407; H05K 2201/10098; H05K 1/0237; H01Q 1/48

(57) ABSTRACT

An antenna device and a printed circuit board are provided. The antenna device is adapted to transmit or receive a signal, and the antenna device includes an antenna dielectric layer, an antenna pattern, and a ground metal layer. The antenna dielectric layer has a first surface and a second surface opposite to each other, wherein a thickness of the antenna dielectric layer is n/4 times a wavelength of the signal, and n is an odd number. The antenna pattern is disposed on the first surface of the antenna dielectric layer. The ground metal layer is disposed on the second surface of the antenna dielectric layer and fully covers the second surface of the antenna dielectric layer.

### CROSS-REFERENCE TO RELATED APPLICATION

This application claims the priority benefit of China application serial no. 201811041315.5, filed on Sep. 7, 2018. The entirety of the above-mentioned patent application is hereby incorporated by reference herein and made a part of this specification.

### BACKGROUND OF THE INVENTION

### Field of the Invention

The disclosure relates to an antenna device and a printed circuit board.

### Description of Related Art

As the demand for transmission rates for wireless communications gradually increases, antennas adapted for high frequency signals (e.g., millimeter wave signals) have gradually become mainstream in the development of antennas. For example, the 802.11ad specification developed by the Wireless Gigabit Alliance (WiGig) proposes data transmission using a frequency band of up to 60 gigahertz (GHz). On the other hand, the 5th generation mobile network (5G) standard developed by the 3rd Generation Partnership Project (3GPP) also proposes data transmission using millimeter waves (30 GHz to 300 GHz). In addition, the rise of the Internet of Vehicles has led to the development of microwave sensing technology. Application frequency bands of radars are also moving from the traditional 24 GHz to 77 GHz, 79 GHz, or higher frequency bands. High frequency radiation applications have become one of the fastest growing areas in the industries.

Currently, when designing an antenna device, it is required to dispose a keep-out area in the ground metal layer to reduce the negative impact of the ground metal layer on the radiation of the antenna. However, the keep-out area will interfere with the signals of other layers. Therefore, there is a need to provide an antenna device that can improve the above problem.

### SUMMARY OF THE INVENTION

The invention is directed to an antenna device and a printed circuit board that can reduce the negative impact of a keep-out area on the radiation of the antenna.

The invention provides an antenna device adapted to transmit or receive a signal. The antenna device includes an antenna dielectric layer, an antenna pattern, and a ground metal layer. The antenna dielectric layer has a first surface and a second surface opposite to each other, wherein a thickness of the antenna dielectric layer is n/4 times a wavelength of the signal, and the n is an odd number. The antenna pattern is disposed on the first surface of the antenna dielectric layer. The ground metal layer is disposed on the second surface of the antenna dielectric layer and fully covers the second surface of the antenna dielectric layer.

According to an embodiment of the invention, the n is 1 when the signal is a wideband signal.

According to an embodiment of the invention, the signal is a millimeter wave signal.

According to an embodiment of the invention, a material of the antenna dielectric layer includes a ceramic material.

According to an embodiment of the invention, a dielectric constant of the antenna dielectric layer is in a range from 10 to 100.

The invention also provides a printed circuit board including a plurality of dielectric layers and a plurality of metal layers. The plurality of metal layers are alternately stacked with the plurality of dielectric layers. One of the plurality of dielectric layers is an antenna dielectric layer having a first surface and a second surface opposite to each other. One of the plurality of metal layers located on the first surface is an antenna pattern. Another of the plurality of metal layers located on the second surface is a ground metal layer fully covering the second surface. The antenna dielectric layer, the antenna pattern, and the ground metal layer are defined as an antenna device adapted to transmit or receive a signal. A thickness of the antenna dielectric layer is n/4 times a wavelength of the signal, and the n is an odd number.

According to an embodiment of the invention, the n is 1 when the signal is a wideband signal.

According to an embodiment of the invention, the signal is a millimeter wave signal.

According to an embodiment of the invention, a material of the antenna dielectric layer includes a ceramic material.

According to an embodiment of the invention, a dielectric constant of the antenna dielectric layer is in a range from 10 to 100.

Based on the above, the invention can improve the radiation gain of the antenna device without disposing any keep-out area, which makes antenna designing more convenient. The radiation gain of the antenna device is not attenuated due to the fact that the metal layer does not have a keep-out area, such that the thickness of the antenna device can conform to the mainstream specifications on the market.

### BRIEF DESCRIPTION OF THE DRAWINGS

The accompanying drawings are included to allow further understanding of the invention, and the drawings are incorporated into the specification and form a part of the specification. The drawings illustrate the embodiments of the invention, and the drawings and the description together are used to interpret the principles of the invention.

FIG. 1A is a schematic diagram of an antenna device according an embodiment of the invention.

FIG. 1B is a cross-sectional view taken along line A-A′ of FIG. 1A.

FIG. 1C is a schematic diagram of a printed circuit board according to an embodiment of the invention.

FIG. 2 is a schematic diagram of a far-field radiation field generated by a single point current at a distance d from a metal plane according to an embodiment of the invention.

FIG. 3A to FIG. 3C are power density/frequency diagrams of a far-field radiation field Ey at different dielectric constants according to an embodiment of the invention.

### DESCRIPTION OF THE EMBODIMENTS

Reference will now be made in detail to the exemplary embodiments of the invention, examples of which are illustrated in the accompanying drawings. Wherever possible, the same reference numbers are used in the drawings and the description to refer to the same or like parts.

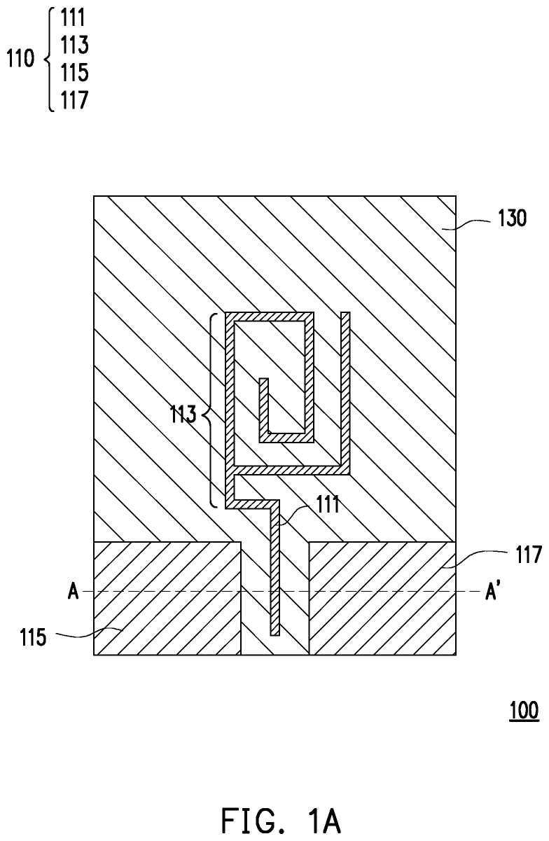

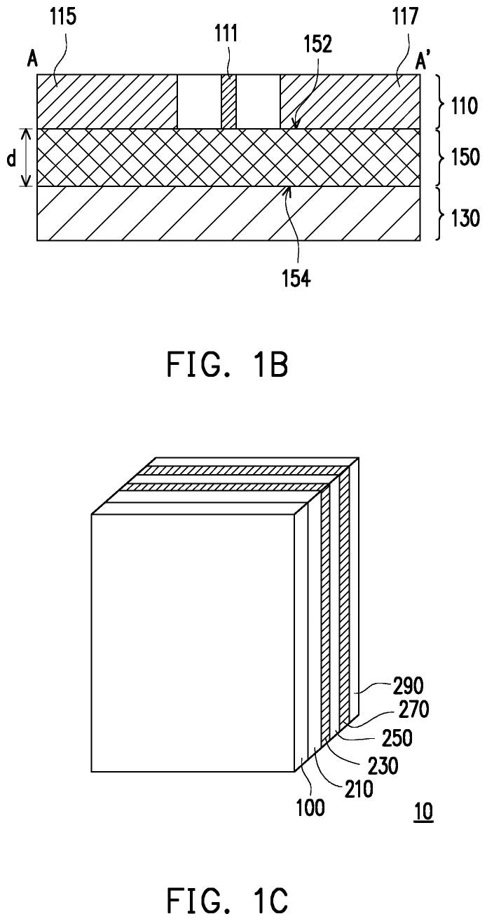

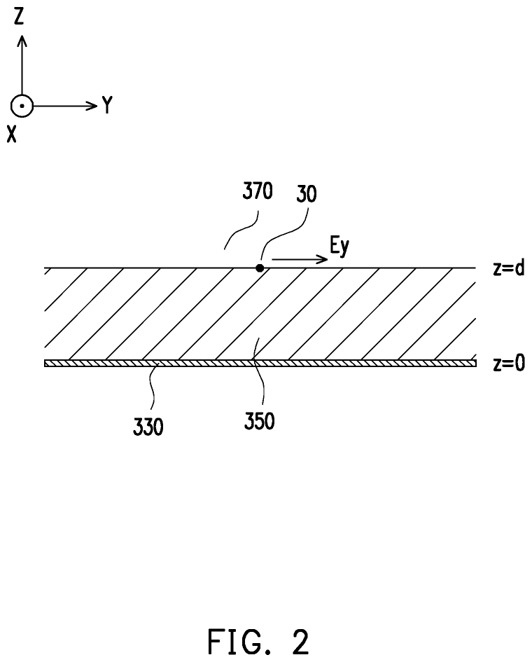

FIG. 1A is a schematic diagram of an antenna device according an embodiment of the invention. FIG. 1B is a cross-sectional view taken along line A-A′ of FIG. 1A. For clarity, an antenna dielectric layer 150 is not shown in FIG. 1A. Referring to FIG. 1A and FIG. 1B, to reduce the negative impact of the keep-out area on the antenna, an embodiment of the invention provides an antenna device 100 which may not have a keep-out area and is adapted to transmit or receive a signal (in particular, a high frequency signal such as a millimeter wave signal). The antenna device 100 includes an antenna dielectric layer 150, an antenna pattern 110, and a ground metal layer 130. The antenna dielectric layer 150 has a first surface 152 and a second surface 154 opposite to each other, wherein a thickness d of the antenna dielectric layer 150 is n/4 times a wavelength of the signal, and n is an odd number. The antenna pattern 110 may be disposed on the first surface 152 of the antenna dielectric layer 150. Here, the antenna pattern 110 may be formed by, for example, etching, printing, or plating, and the form of the antenna pattern 110 may be adjusted, for example, to be an L-shaped antenna, an inverted-F antenna (IFA), or a planar inverted-F antenna (PIFA), according to the circumstance of use, and the invention is not limited thereto.

The antenna pattern 110 of the present embodiment may be a coplanar waveguide (CPW) and may include a signal feed-in part 111, a radiation part 113, and two symmetric groundings 115 and 117. However, the invention is not limited thereto. In some embodiments, the signal feed-in part 111 of the antenna pattern 110 may be connected with a signal feed-in point (not shown) of an external circuit (not shown) through a high frequency transmission line. Accordingly, the signal feed-in part 111 can transmit a signal from the signal feed-in point to the radiation part 113. In some embodiments, the two symmetric groundings 115 and 117 may provide electromagnetic shielding for the signal feed-in part 111.

The ground metal layer 130 may be disposed on the second surface 154 of the antenna dielectric layer 150 and fully cover the second surface 154 of the antenna dielectric layer 150. In other words, the ground metal layer 130 of the present embodiment does not need to include a keep-out area disposed corresponding to the antenna pattern 110, the design of the antenna device 100 without a keep-out area is more convenient. Moreover, the complete ground metal layer 130 (i.e., the ground metal layer 130 without a keep-out area) can effectively block signal interference from outside (e.g., from other circuit wirings on the printed circuit board).

The antenna dielectric layer 150 is located between the antenna pattern 110 and the ground metal layer 130. For example, the antenna dielectric layer 150 of the embodiment is in direct contact with the antenna pattern 110 and the ground metal layer 130. The antenna dielectric layer 150 may be a lossless material such as silicon dioxide, silicon nitride, hafnium oxide, or a ceramic material (e.g., low temperature co-fired ceramic (LTCC)), and the invention is not limited thereto. The antenna dielectric layer 150 has a dielectric constant K, wherein the dielectric constant K may be in the range from 10 to 100. In a conventional antenna device, the dielectric constant adopted for the antenna dielectric layer is about 2 to 3. In that case, the metal layer adjacent to the conventional antenna dielectric layer will approximate the perfect electric conductor (PEC), and the above metal layer adjacent to the antenna dielectric layer will weaken the radiation generated by the antenna device. In contrast, the dielectric constant K of the antenna dielectric layer 150 of the present embodiment is higher than the dielectric constant (about 2 to 3) adopted for the conventional antenna dielectric layer. Therefore, the ground metal layer 130 adjacent to the antenna dielectric layer 150 will not weaken the radiation generated by the antenna device 100 (or the antenna pattern 110).

The design of the ground metal layer 130 fully covering the antenna dielectric layer 150 (i.e., the ground metal layer 130 without a keep-out area) may cause the ground metal layer 130 of the antenna device 100 to generate a reverse mapping current corresponding to the current on the antenna pattern 110. Accordingly, the value of the dielectric constant K of the antenna dielectric layer 150 may be increased to prevent generation of an inverted phase mapping current that may cancel the antenna current radiation field. Furthermore, to improve the radiation gain of the antenna device 100 in the case where the ground metal layer 130 does not have a keep-out area, the dielectric constant K may be adjusted to cause the thickness d of the antenna dielectric layer 150 to be n/4 times the wavelength (e.g., the wavelength of the plane wave) of the signal transmitted or received by the antenna device 100, and n is an odd number. Since the antenna device 100 may be adapted for transmission of a high frequency signal with a shorter wavelength (e.g., a millimeter wave signal (about 30 to 300 GHz)), the invention can adjust the dielectric constant K to cause the thickness d of the antenna dielectric layer 150 to be n/4 times the wavelength of the signal transmitted or received by the antenna device 100 without increasing (or without increasing too much) the thickness d. The above design can prevent the radiation gain of the antenna device 100 from attenuation resulting from the fact that the ground metal layer 130 does not have a keep-out area.

FIG. 1C is a schematic diagram of a printed circuit board according to an embodiment of the invention. The antenna device 100 of FIG. 1A may be an independent component or may be integrated with other components in a printed circuit board (PCB) as shown in FIG. 1C for use. Referring to FIG. 1B and FIG. 1C, a printed circuit board 10 may be a multilayer PCB formed by stacking a plurality of dielectric layers 210, 250, 290, 150 and a plurality of metal layers 230, 270, 110, 130, and an overall thickness of the printed circuit board is, for example, 0.6 mm to 1.2 mm.

Specifically, one of the dielectric layers 210, 250, 150 is the antenna dielectric layer 150, and the antenna dielectric layer 150 has a first surface 152 and a second surface 154 opposite to each other. One of the metal layers 230, 270, 110, 130 located on the first surface 152 is the antenna pattern 110, another of the metal layers 230, 270, 110, 130 located on the second surface 154 is the ground metal layer 130, and the ground metal layer 130 fully covers the second surface 130. The antenna dielectric layer 150, the antenna pattern 110, and the ground metal layer 130 are defined as the antenna device 100 adapted to transmit or receive a signal. Moreover, a thickness d of the antenna dielectric layer 150 is n/4 times a wavelength of the signal, and n is an odd number. The antenna pattern 110 may be located at the top layer of the printed circuit board 10, or the antenna pattern 110 may also be located at the mid-layer of the printed circuit board 10. If the antenna pattern 110 is located at the mid-layer of the printed circuit board 10, a metal pattern is not disposed right above the antenna pattern 110 to thereby facilitate the operation of the antenna device 100. With the ground metal layer 130 not having a keep-out area, antenna designing is more convenient, and the complete ground metal layer 130 (i.e., the ground metal layer 130 without a keep-out area) can block signal interference from other layers (e.g., the metal layer 230 or the metal layer 270) of the printed circuit board 10.

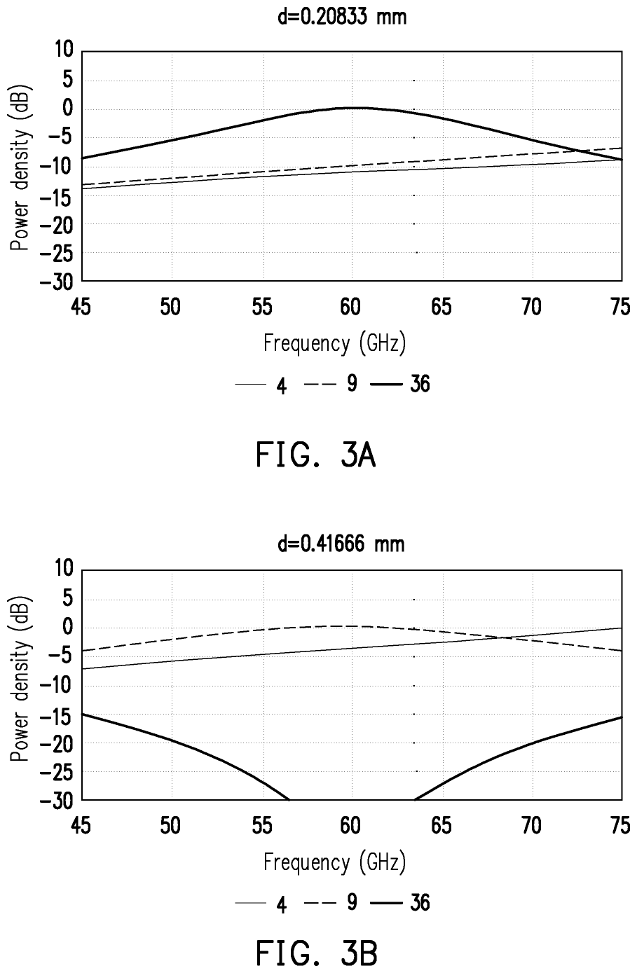

FIG. 2 is a schematic diagram of a far-field radiation field Ey generated by a single point current 30 at a distance d from a metal plane 330 according to an embodiment of the invention. In FIG. 2, assuming that the metal plane 330 is an infinite metal plane and the point current 30 generates a far-field radiation field Ey to a mediumless wave transmission space 370 at a distance d from the metal plane 330 (i.e., the thickness of an antenna dielectric layer 350 is d), then Equation (1) of the far-field radiation field Ey may be as follows:

$$Ey ∝ \frac{{k}_{0}}{ω} \cdot \frac{1 - {e}^{j 2 {k}_{1} d}}{( 1 - \sqrt{{ɛ}_{r}} ) - ( 1 + \sqrt{{ɛ}_{r}} ) \cdot {e}^{j 2 {k}_{1} d}} \vert \qquad Equation ( 1 )$$

In Equation (1), εᵣ=ε/ε₀, where ε₀ is a dielectric constant of the mediumless wave transmission space 370 and ε is a dielectric constant of the antenna dielectric layer 350. Ey is an electric field intensity generated by the point current 30 in the y direction in the wave transmission space 370, k₀ is a propagation constant of the mediumless wave transmission space 370, k₁ is a propagation constant (k₁=\sqrt{εᵣ}·k₀)of the antenna dielectric layer 350, j is a complex number (0, 1), and ω is an angular wavenumber.

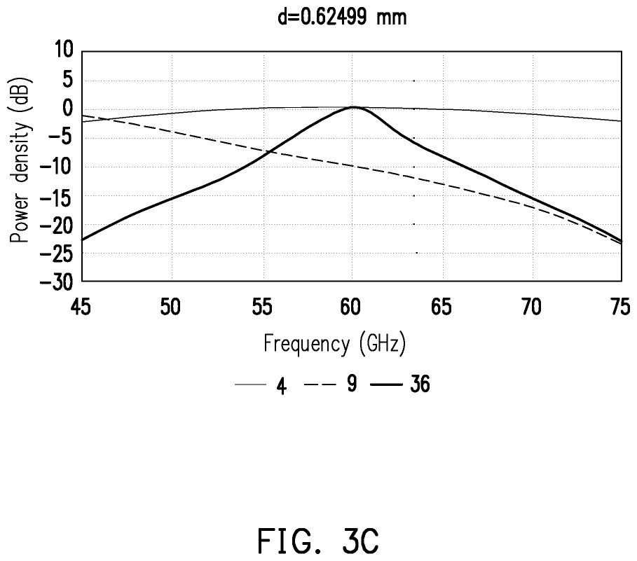

Based on Equation (1), power density/frequency diagrams of the far-field radiation field Ey generated by the point current 30 at different dielectric constants may be illustrated, as shown in FIG. 3A to FIG. 3C. FIG. 3A to FIG. 3C are power density/frequency diagrams of the far-field radiation field Ey at different dielectric constants according to an embodiment of the invention.

Referring to FIG. 2 and FIG. 3A, in FIG. 3A, assuming that the frequency of the point current 30 is 60 GHz and the thickness of the antenna dielectric layer 350 is d=0.20833 mm, then according to FIG. 3A, among the dielectric constants of 4, 9, and 36 of the antenna dielectric layer 350, the far-field radiation field Ey, at the dielectric constant of 36, has the highest power density (unit: dB (decibel)) with the center frequency of 60 GHz. Therefore, adopting the dielectric constant of 36 is most favorable for radiation of the point current 30. In this case, the thickness d=0.20833 mm is very close to ¼ times the wavelength of the 60 GHz signal in the antenna dielectric layer 350. In other words, when the thickness d of the antenna dielectric layer 350 is equal to ¼ times the wavelength of the signal, the far-field radiation field Ey has a better power density at the center frequency of 60 GHz, and the metal plane 330 is approximately equivalent to a perfect magnetic conductor (PMC). Accordingly, the point current 30 will cause the metal plane 330 to generate a forward mapping current, and the mapping current can increase the gain of the far-field radiation field Ey to about twice that of the original far-field radiation field Ey.

Next, referring to FIG. 2 and FIG. 3B, in FIG. 3B, assuming that the frequency of the point current 30 is 60 GHz and the thickness of the dielectric layer 350 is d=0.41666 mm, then according to FIG. 3B, among the dielectric constants of 4, 9, and 36 of the antenna dielectric layer 350, the far-field radiation field Ey, at the dielectric constant of 9, has the highest power density with the center frequency of 60 GHz. Therefore, adopting the dielectric constant 9 is most favorable for the radiation of the point current 30. In this case, the thickness d=0.41666 mm is very close to ¼ times the wavelength of the 60 GHz signal in the antenna dielectric layer 350. In other words, when the thickness d of the antenna dielectric layer 350 is equal to ¼ times the wavelength of the signal, the far-field radiation field Ey has a better power density at the center frequency of 60 GHz, and the metal plane 330 is approximately equivalent to the perfect magnetic conductor. On the other hand, among the dielectric constants of 4, 9, and 36, at the dielectric constant of 36, the far-field radiation field Ey has the lowest power density at the center frequency of 60 GHz. Therefore, adopting the dielectric constant of 36 is most unfavorable for the radiation of the point current 30. In this case, the thickness d=0.41666 mm is very close to 2/4 times the wavelength of the 60 GHz signal in the antenna dielectric layer 350. In other words, when the thickness d of the antenna dielectric layer 350 is equal to 2/4 times (or n/4 times, and n is an even number) of the wavelength of the signal, the far-field radiation field Ey has a poorer power density at the center frequency of 60 GHz.

Next, referring to FIG. 2 and FIG. 3C, in FIG. 3C, assuming that the frequency of the point current 30 is 60 GHz and the thickness of the antenna dielectric layer 350 is d=0.62499, then according to FIG. 3C, among the dielectric constants of 4, 9, and 36 of the antenna dielectric layer 350, the far-field radiation field Ey, at the dielectric constant of 4, has the highest power density with the center frequency of 60 GHz. Therefore, adopting the dielectric constant of 4 is most favorable for the radiation of the point current 30. In this case, the thickness d=0.62499 is very close to ¼ times the wavelength of the 60 GHz signal in the antenna dielectric layer 350. In other words, when the thickness d of the antenna dielectric layer 350 is equal to ¼ times the wavelength of the signal, the far-field radiation field Ey has a better power density at the center frequency of 60 GHz, and the metal plane 330 is approximately equivalent to the perfect magnetic conductor. On the other hand, among the dielectric constants of 4, 9, and 36 of the antenna dielectric layer 350, the far-field radiation field Ey, at the dielectric constant of 36, also has the highest power density with the center frequency of 60 GHz. Therefore, adopting the dielectric constant of 36 is favorable for the radiation of the point current 30. In this case, the thickness d=0.62499 is very close to ¾ times the wavelength of the 60 GHz signal in the antenna dielectric layer 350. In other words, when the thickness d of the antenna dielectric layer 350 is equal to ¾ times the wavelength of the signal, the far-field radiation field Ey has a better power density at the center frequency of 60 GHz, and the metal plane 330 is approximately equivalent to the perfect magnetic conductor. In the present embodiment, when the dielectric constant of 4 or the dielectric constant of 36 is adopted, the far-field radiation field Ey has a better power density at the center frequency of 60 GHz. However, at a frequency band around the center frequency of 60 GHz (e.g., a frequency band of 55 GHz to 59 GHz or 61 GHz to 65 GHz), the power density gain at the dielectric constant of 4 is better than that at the dielectric constant of 36. In other words, when the point current 30 or the far-field radiation field Ey is a wideband signal, it is more suitable to adopt the dielectric constant of 4, namely, to cause the thickness d of the antenna dielectric layer 350 to be ¼ times the wavelength of the signal (of the point current 30 or the far-field radiation field Ey).

In summary of the above, the invention can improve the radiation gain of the antenna device without disposing any keep-out area. The antenna device without any keep-out area retains the complete and intact ground metal layer, which makes antenna designing more convenient. In addition, the invention can adjust the dielectric constant to have the thickness of the antenna dielectric layer to be n/4 times the wavelength of the signal transmitted or received by the antenna device without increasing (or increasing too much) the thickness of the antenna dielectric layer. The above design can prevent the radiation gain of the antenna device from attenuation resulting from the fact that the ground metal layer does not have a keep-out area, and the thickness of the antenna device can conform to the mainstream specifications on the market. Thus, the radiation capability of the antenna device in the printed circuit board of the invention is no longer limited by the adjacent metal plane.

Lastly, it shall be noted that the foregoing embodiments are meant to illustrate, rather than limit, the technical solutions of the invention. Although the invention has been detailed with reference to the foregoing embodiments, persons ordinarily skilled in the art shall be aware that they may still make modifications to the technical solutions recited in the foregoing embodiments or make equivalent replacements of part or all of the technical features therein, and these modifications or replacements do not cause the nature of the corresponding technical solutions to depart from the scope of the technical solutions of the embodiments of the invention.

What is claimed is:

1. An antenna device adapted to transmit or receive a signal, comprising:
an antenna dielectric layer having a first surface and a second surface opposite to each other, wherein a thickness of the antenna dielectric layer is n/4 times a wavelength of the signal, and the n is an odd number;
an antenna pattern disposed on the first surface of the antenna dielectric layer; and
a ground metal layer disposed on the second surface of the antenna dielectric layer and fully covering the second surface of the antenna dielectric layer.

2. The antenna device according to claim 1, wherein the n is 1 when the signal is a wideband signal.

3. The antenna device according to claim 1, wherein the signal is a millimeter wave signal.

4. The antenna device according to claim 1, wherein a material of the antenna dielectric layer comprises a ceramic material.

5. The antenna device according to claim 1, wherein a dielectric constant of the antenna dielectric layer is in a range from 10 to 100.

6. A printed circuit board comprising:
a plurality of dielectric layers; and
a plurality of metal layers alternately stacked with the plurality of dielectric layers,
wherein one of the plurality of dielectric layers is an antenna dielectric layer having a first surface and a second surface opposite to each other, one of the plurality of metal layers located on the first surface is an antenna pattern, and another of the plurality of metal layers located on the second surface is a ground metal layer fully covering the second surface, wherein the antenna dielectric layer, the antenna pattern, and the ground metal layer are defined as an antenna device adapted to transmit or receive a signal, wherein a thickness of the antenna dielectric layer is n/4 times a wavelength of the signal, and the n is an odd number.

7. The printed circuit board according to claim 6, wherein the n is 1 when the signal is a wideband signal.

8. The printed circuit board according to claim 6, wherein the signal is a millimeter wave signal.

9. The printed circuit board according to claim 6, wherein a material of the antenna dielectric layer comprises a ceramic material.

10. The printed circuit board according to claim 6, wherein a dielectric constant of the antenna dielectric layer is in a range from 10 to 100.
